(19) United States
(12) Patent Application Publication
(10) Pub. No.: US 2017/0292039 A1
(43) Pub. Date: Oct. 12, 2017

(54) POLISHING COMPOSITION, METHOD FOR MANUFACTURING SAME, AND POLISHING METHOD

(71) Applicant: FUJIMI INCORPORATED, Kiyosu-shi, Aichi (JP)

(72) Inventors: Takeki SATO, Aichi (JP); Koichi SAKABE, Aichi (JP)

(73) Assignee: FUJIMI INCORPORATED, Kiyosu-shi, Aichi (JP)

(21) Appl. No.: 15/514,172

(22) PCT Filed: Jul. 27, 2015
(86) PCT No.: PCT/JP2015/003754

§ 371 Date: Mar. 24, 2017

(30) Foreign Application Priority Data
Sep. 30, 2014 (JP) 2014-200720

(51) Int. Cl. C09G 1/02; B24B 37/04; H01L 21/321

(52) U.S. Cl. CPC C09G 1/02; H01L 21/3212; B24B 37/044

(57) ABSTRACT

There is provided a polishing composition capable of polishing a polishing object including elemental silicon, a silicon compound, metals and the like, especially including tungsten, at a high polishing rate. The polishing composition includes: colloidal silica with organic acid immobilized to a surface thereof; hydrogen peroxide; and salt, the salt being at least one of ammonium nitrate and ammonium sulfate.

### TECHNICAL FIELD

The present invention relates to compositions for polishing (hereinafter polishing compositions), methods for manufacturing such a polishing composition, and methods for polishing.

### BACKGROUND ART

Manufacturing process of semiconductor devices include a step of polishing an object made of elemental silicon (Si), silicon compounds, metals or the like. In this step, metals and interlayer dielectrics are required to be polished at a high polishing rate. Some of conventionally used polishing compositions to polish metals and interlayer dielectrics include abrasives and oxidant. For instance, Patent Literature 1 discloses a polishing composition for metal, which includes abrasives, oxidant, a protection-film forming agent, acid and water. Patent Literature 2 discloses a polishing composition for metal, which includes oxidant and colloidal silica including at least part of silicon atoms on the surface that is displaced with aluminum atoms. Patent Literature 3 discloses a polishing composition, which includes silica with organic acid immobilized to the surface, and oxidant. These conventional polishing components, however, do not satisfy user's demand on the polishing rate of metals and interlayer dielectrics fully.

### CITATION LIST

### Patent Literatures

PTL 1: JP 2009-152647 A

PTL 2: JP 2007-207785 A

PTL 3: JP 2013-138053 A

### SUMMARY OF INVENTION

### Technical Problem

The present invention aims to provide a polishing composition, a method manufacturing the polishing composition, and a method for polishing to solve the problems of the conventional techniques as stated above. According to the present invention, a polishing object including elemental silicon, a silicon compound, metals and the like, especially including tungsten, can be polished at a high polishing rate.

### Solution to Problem

To solve the above problems, a polishing composition according to one aspect of the present invention includes: colloidal silica with organic acid immobilized to a surface of the colloidal silica; hydrogen peroxide; and salt, the salt being at least one of ammonium nitrate and ammonium sulfate.

In the polishing composition according to the above aspect, the organic acid may be sulfonic acid.

In the polishing composition according to the above aspect, the polishing composition may have pH of 5 or less.

In the polishing composition according to the above aspect, content of the salt may be 0.01% by mass or more and 5.0% by mass or less.

In the polishing composition according to the above aspect, content of the hydrogen peroxide may be 0.01% by mass or more and 10% by mass or less.

In the polishing composition according to the above aspect, the polishing composition can be for polishing tungsten.

A method for polishing according to another aspect of the present invention includes polishing a polishing object using the polishing composition according to the above aspect. In this method for polishing, the polishing object may include tungsten.

A method for manufacturing a polishing composite according to another aspect of the present invention is for manufacturing the polishing composition according to the above aspect, and includes mixing the colloidal silica with organic acid immobilized to the surface, the hydrogen peroxide, the salt and fluid medium.

A substrate according to another aspect of the present invention has a surface that is polished using the polishing composition according to the above aspect.

A method for manufacturing a substrate according to another aspect of the present invention includes polishing a surface of the substrate using the polishing composition according to the above aspect.

### Advantageous Effects of Invention

A polishing composition and a method for polishing of the present invention are capable of polishing a polishing object including elemental silicon, a silicon compound, metals and the like, especially including tungsten, at a high polishing rate. A method for manufacturing a polishing composition of the present invention can manufacture a polishing composition capable of polishing a polishing object including elemental silicon, a silicon compound, metals and the like, especially including tungsten, at a high polishing rate.

### DESCRIPTION OF EMBODIMENTS

The following describes embodiments of the present invention in details. A polishing composition of the present embodiment includes colloidal silica with organic acid immobilized to the surface, hydrogen peroxide and salt. This salt is at least one of ammonium nitrate and ammonium sulfate. This polishing composition can be prepared by mixing colloidal silica with organic acid immobilized to the surface, hydrogen peroxide, salt that is at least one of ammonium nitrate and ammonium sulfate, and fluid medium such as water or organic solvent.

This polishing composition is suitably used for polishing of an object such as elemental silicon, silicon compounds or metals, e.g., for polishing the surface of a wiring substrate made of silicon, containing elemental silicon, a silicon compound, or metals, during the manufacturing process of a semiconductor device. The polishing composition is particularly suitably used for polishing tungsten (W). Polishing using this polishing composition enables polishing of an object including elemental silicon, silicon compounds or metals, especially including tungsten, at a high polishing rate.

The following describes the polishing composition of the present embodiment in details.

### 1. Colloidal Silica with Organic Acid Immobilized to the Surface

### 1-1 Immobilizing of Organic Acid

Colloidal silica with organic acid immobilized to the surface functions as abrasives in the polishing composition. Organic acid may be immobilized to the surface of colloidal silica by chemically bonding a functional group of the organic acid with the surface of colloidal silica, for example. When colloidal silica and organic acid simply coexist, such organic acid is not immobilized with the colloidal silica.

When sulfonic acid as one type of the organic acid is immobilized to colloidal silica, this is achieved by the method described in “Sulfonic acid-functionalized silica through quantitative oxidation of thiol groups”, Chem. Commun. 246-247 (2003), for example. Specifically, colloidal silica with sulfonic acid immobilized to the surface can be obtained by letting a silane coupling agent having a thiol group, such as 3-mercaptopropyltrimethoxysilane, react with a hydroxyl group at the surface of the colloidal silica for coupling and then oxidizing the thiol group with hydrogen peroxide.

Alternatively, carboxylic acid may be immobilized to the surface of colloidal silica, for example, by the method described in “Novel Silane Coupling Agents Containing a Photolabile 2-Nitrobenzyl Ester for Introduction of a Carboxy Group on the Surface of Silica Gel”, Chemistry Letters, 3,228-229 (2000). Specifically, colloidal silica with carboxylic acid immobilized to the surface can be obtained by letting a silane coupling agent containing a photoreactive 2-nitrobenzyl ester react with a hydroxyl group at the surface of the colloidal silica for coupling and then irradiating with light.

Alternatively, organic acids such as sulfinic acid and phosphonic acid may be immobilized to the surface of colloidal silica.

Since typical colloidal silica has the value of zeta potential close to zero under the acid condition, such colloidal silica particles do not repel one another electrically but easily coagulate under the acid condition. On the contrary, since colloidal silica with organic acid immobilized to the surface is surface-modified so as to have a relatively large value of zeta potential even under the acid condition, colloidal silica particles repel one another intensively even under the condition, and are dispersed favorably. As a result, the polishing composition can have improved storage stability.

### 1-2 Aspect Ratio

Preferably colloidal silica with organic acid immobilized to the surface has an aspect ratio that is less than 1.4, preferably 1.3 or less and more preferably 1.25 or less. Such an aspect ratio can suppress surface defects on the surface of the polishing object after polishing using the polishing composition, which results from the shape of the abrasives.

The aspect ratio can be found as follows. A minimum rectangle that is circumscribed around each colloidal silica particle is found, and the long side length of the rectangle is divided by the short side length. The average of these values is the aspect ratio, and can be found using an image of the colloidal silica particles obtained with a scanning electron microscope electron microscope and using typical image analysis software.

### 1-3 Primary Particle Diameter

The average primary particle diameter of colloidal silica with organic acid immobilized to the surface is preferably 5 nm or more, more preferably 7 nm or more and further preferably 10 nm or more. The average primary particle diameter of colloidal silica with organic acid immobilized to the surface is preferably 200 nm or less, more preferably 150 nm or less, and further preferably 100 nm or less.

Such a range leads to the improvement in polishing rate of a polishing object by the polishing composition. Such a range can suppress surface defects more on the surface of the polishing object after polishing using the polishing composition.

The average primary particle diameter of colloidal silica can be calculated in accordance with the specific surface area of the colloidal silica measured by the BET method, for example.

### 1-4 Secondary Particle Diameter

The average secondary particle diameter of colloidal silica with organic acid immobilized to the surface is preferably 10 nm or more, more preferably 15 nm or more and further preferably 20 nm or more. The average secondary particle diameter of colloidal silica with organic acid immobilized to the surface is preferably 300 nm or less, more preferably 260 nm or less, and further preferably 220 nm or less.

Such a range leads to the improvement in polishing rate of a polishing object by the polishing composition. Such a range can suppress surface defects on the surface of the polishing object after polishing using the polishing composition.

The secondary particles here refer to the particles formed by assembly of colloidal silica (primary particles) with organic acid immobilized to the surface in the polishing composition. The average secondary particle diameter of these secondary particles can be measured by dynamic light scattering, for example.

### 1-5 Content of Colloidal Silica

The content of colloidal silica with organic acid immobilized to the surface in the polishing composition as a whole is preferably 0.005% by mass or more, more preferably 0.05% by mass or more, and further preferably 0.1% by mass or more. Such a range can lead to the improvement in polishing rate of a polishing object.

The content of colloidal silica with organic acid immobilized to the surface in the polishing composition as a whole is preferably 50% by mass or less, more preferably 30% by mass or less, and further preferably 20% by mass or less. Such a range leads to reduction in cost of the polishing composition.

### 2. Salt

The polishing composition of the present embodiment includes, as salt, at least one of ammonium nitrate and ammonium sulfate. When the polishing composition includes at least one of ammonium nitrate and ammonium sulfate, the polishing rate of a polishing object such as elemental silicon, a silicon compound and metals (especially tungsten) by the polishing composition can be improved.

The content of salt in the polishing composition as a whole is preferably 0.01% by mass or more, more preferably 0.05% by mass or more, and further preferably 0.1% by mass or more. Such a range can lead to further improvement in polishing rate of a polishing object.

The content of salt in the polishing composition as a whole is preferably 5.0% by mass or less, more preferably 3.0% by mass or less, and further preferably 2.5% by mass or less. Such a range leads to reduction in cost of the polishing composition.

### 3. Hydrogen Peroxide

The polishing composition of the present embodiment includes hydrogen peroxide. The oxidation effect of the hydrogen peroxide forms an oxide film on the surface of the polishing object, which facilitates the polishing.

The more hydrogen peroxide is included in the polishing composition as a whole, the more improved polishing rate of a polishing object is achieved by such a polishing composition. Therefore preferable content of hydrogen peroxide in the polishing composition as a whole is 0.01% by mass or more, more preferably 0.05% by mass or more.

The less hydrogen peroxide is included in the polishing composition as a whole, the less cost is required of the polishing composition. Disposal of the polishing composition after the polishing, i.e., burden on the waste liquid disposal also can be reduced. Therefore the content of hydrogen peroxide in the polishing composition as a whole is preferably 10% by mass or less, more preferably 5% by mass or less.

### 4. Fluid Medium

Fluid medium functions as a dispersion medium or a solvent to disperse or dissolve the components in the polishing composition (colloidal silica with organic acid immobilized to the surface, hydrogen peroxide, salt, additives and the like). Organic solvents and water can be used for the fluid medium. Although these media may be used singly or in combination of two or more types of them, water is included preferably. From the viewpoint of prevention of inhibiting of the action of other components, water not containing impurities as much as possible is preferable. Specifically pure water or ultrapure water in which impurity ions are removed by an ion exchange resin and then foreign matters are removed through a filter, or distilled water is preferable.

### 5. Additives

Various additives, such as pH adjusting agent, oxidant, complexing agent, surfactant, water-soluble polymer, and fungicide, may be added to the polishing composition so as to improve the performance of the polishing composition.

### 5-1 pH Adjusting Agent

The value of pH of the polishing composition is preferably 1 or more, more preferably 1.5 or more and further preferably 2 or more. A polishing composition having higher value of pH can be dealt with easily. A lower value of pH of the polishing composition means less dissolution of colloidal silica with organic acid immobilized to the surface. Therefore the value of pH of the polishing composition is preferably less than 12, more preferably 11 or less, further preferably 10 or less, and particularly preferably 5 or less.

The value of pH of the polishing composition may be adjusted by adding a pH adjusting agent. Such a pH adjusting agent that is used as needed to adjust the value of pH of the polishing composition to a desired value may be either acid or alkali, and may be either an inorganic compound or an organic compound.

Specific examples of the acid as the pH adjusting agent include inorganic acid, and organic acid such as carboxylic acid or organic sulfuric acid. Specific examples of inorganic acid include sulfuric acid, nitric acid, boric acid, carbonic acid, hypophosphorous acid, phosphorous acid, and phosphoric acid. Specific examples of carboxylic acid include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid; glyceric acid, oxalic acid, malonic acid, succinic acid, glutaric acid, adipic acid, pimelic acid, maleic acid, phthalic acid, malic acid, tartaric acid, citric acid and lactic acid. Specific examples of organic sulfuric acid include methanesulfonic acid, ethanesulfonic acid, and isethionic acid. These acids may be used singly or in combination of two or more types of them.

Specific examples of the base as the pH adjusting agent include hydroxides of alkali metals or salts thereof, hydroxides of alkali earth metals or salts thereof, quaternary ammonium hydroxide or salts thereof, ammonia, and amines.

Specific examples of alkali metals include potassium and sodium. Specific examples of alkali earth metals include calcium and strontium. Specific examples of salts include carbonates, hydrogen carbonates, hydrosulfates, and acetates. Specific examples of quaternary ammoniums include tetramethylammonium, tetraethylammonium, and tetrabutylammonium.

Specific examples of quaternary ammonium hydroxide compounds include quaternary ammonium hydroxide or a salt thereof, and their specific examples include tetramethylammonium hydroxide, tetraethylammonium hydroxide, and tetrabutylammonium hydroxide.

Specific examples of amine include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, N-methylpiperazine and guanidine.

These bases can be used singly or in combination of two or more types of them.

Of these bases, ammonia, ammonium salt, alkali metal hydroxide, alkali metal salt, quaternary ammonium hydroxide compounds, and amines are preferable, and ammonia, potassium compounds, sodium hydroxide, quaternary ammonium hydroxide compounds, ammonium hydrogen carbonate, ammonium carbonate, sodium hydrogen carbonate, and sodium carbonate are more preferable.

More preferably the polishing composition includes a potassium compound as the base from the viewpoint of prevention of metallic contamination. Examples of potassium compound include hydroxides of potassium and potassium salts, and their specific examples include potassium hydroxide, potassium carbonate, potassium hydrogen carbonate, potassium sulfate, potassium acetate and potassium chloride.

### 5-2 Oxidant

The polishing composition of the present embodiment may include other types of oxidants as well as hydrogen peroxide as desired. Specific examples of oxidant include peracetic, percarbonate, urea peroxide, perchloric acid, and persulfate. Specific examples of persulfate include sodium persulfate, potassium persulfate, and ammonium persulfate. These oxidants may be used singly or in combination of two or more types of them. Of these oxidants, persulfate and hydrogen peroxide are preferable.

### 5-3 Complexing Agent

In order to improve the polishing rate of a polishing object by the polishing composition, a complexing agent may be added to the polishing composition. The complexing agent has an action of chemically etching the surface of the polishing object. Specific examples of the complexing agent include inorganic acid or a salt thereof, organic acid or a salt thereof, a nitrile compound, amino acid, and a chelating agent. These complexing agents may be used singly or in combination of two or more types of them. For the complexing agent, a commercial product or a synthetic product may be used.

Specific examples of the inorganic acid include hydrochloric acid, sulfuric acid, nitric acid, carbonic acid, boric acid, tetrafluoroboric acid, hypophosphorous acid, phosphorous acid, phosphoric acid, and pyrophosphoric acid.

Specific examples of the organic acid include a carboxylic acid and a sulfonic acid. Specific examples of the carboxylic acid include a monovalent carboxylic acid, such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, lactic acid, glycolic acid, glyceric acid, benzoic acid, and salicylic acid, and a polyvalent carboxylic acid such as oxalic acid, malonic acid, succinic acid, glutaric acid, gluconic acid, adipic acid, pimelic acid, maleic acid, phthalic acid, fumaric acid, malic acid, tartaric acid, and citric acid. Specific examples of sulfonic acid include methanesulfonic acid, ethanesulfonic acid, and isethionic acid.

As the complexing agent, a salt of these inorganic acids or organic acids may be used. In particular, in the case where a salt of a weak acid and a strong base, a salt of a strong acid and a weak base, or a salt of a weak acid and a weak base is used, buffering action of pH can be expected. Examples of the salt include potassium chloride, sodium sulfate, potassium nitrate, potassium carbonate, potassium tetrafluoroborate, potassium pyrophosphate, potassium oxalate, trisodium citrate, (+)-potassium tartrate, and potassium hexafluorophosphate.

Specific examples of nitrile compound include acetonitrile, aminoacetonitrile, propionitrile, butyronitrile, isobutyronitrile, benzonitrile, glutarodinitrile, and methoxyacetonitrile.

Specific examples of the amino acid include glycine, α-alanine, β-alanine, N-methylglycine, N,N-dimethylglycine, 2-aminobutyric acid, norvaline, valine, leucine, norleucine, isoleucine, phenylalanine, proline, sarcosine, ornithine, lysine, taurine, serine, threonine, homoserine, tyrosine, bicine, tricine, 3,5-diiodo-tyrosine, β-(3,4-dihydroxyphenyl)-alanine, thyroxine, 4-hydroxy-proline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, δ-hydroxy-lysine, creatine, histidine, 1-methyl-histidine, 3-methyl-histidine, and tryptophan.

Specific examples of the chelating agent include nitrilotriacetic acid, diethylenetriaminepenta-acetic acid, ethylenediaminetetraacetic acid, N,N,N-trimethylene phosphonic acid, ethylenediamine-N,N,N′, N′-tetramethylene-sulfonic acid, trans-cyclohexanediaminetetraacetic acid, 1,2-diaminopropane tetraacetic acid, glycol ether diaminetetraacetic acid, ethylenediamine orthohydroxyphenylacetic acid, ethylenediamine disuccinic acid (SS form), N-(2-carboxylate ethyl)-L-aspartic acid, β-alanine diacetic acid, 2-phosphonobutane-1,2,4-tricarboxylic acid, 1-hydroxyethylidene-1,1-diphosphonic acid, N,N′-bis(2-hydroxybenzyl)ethylenediamine-N,N′-diacetic acid, and 1,2-dihydroxybenzene-4,6-disulfonic acid.

Of them, at least one type selected from the group consisting of an inorganic acid or a salt thereof, a carboxylic acid or a salt thereof, and a nitrile compound is preferable, and from the viewpoint of stability of the complex structure with a metal compound included in the polishing object, an inorganic acid or a salt thereof is more preferable. When one (e.g., various types of acids) having a pH adjusting function is used as the various types of complexing agents as stated above, such a complexing agent may be used as at least a part of the pH adjusting agent.

The lower limit of the content of the complexing agent in the polishing composition as a whole is not particularly limited because the complexing agent exerts its effect even in a small amount. Preferable content of the complexing agent in the polishing composition as a whole is 0.001 g/L or more, more preferably 1 g/L or more because the more complexing agent is included, the more improved polishing rate of a polishing object is achieved by such a polishing composition.

The less complexing agent is included in the polishing composition as a whole, the less polishing object is dissolved, and so the flatness of the surface after polishing can be improved. Therefore the content of the complexing agent in the polishing composition as a whole is preferably 20 g/L or less, more preferably 15 g/L or less.

### 5-4 Surfactant

Surfactant may be added to the polishing composition. Since surfactant has an action to give hydrophilic property to the polished surface of the polishing object after the polishing, the polishing object after the polishing can have good washing efficiency, and adhesion of dirt, for example, to the surface can be suppressed. For the surfactant, any one of an anionic surfactant, a cationic surfactant, an amphoteric surfactant, and a nonionic surfactant can be used.

Specific examples of the anionic surfactant include polyoxyethylene alkyl ether acetic acid, polyoxyethylene alkyl sulfuric acid ester, alkyl sulfuric acid ester, polyoxyethylene alkyl ether sulfuric acid, alkyl ether sulfuric acid, alkylbenzene sulfonic acid, alkyl phosphoric acid ester, polyoxyethylene alkyl phosphoric acid ester, polyoxyethylene sulfosuccinic acid, alkylsulfosuccinic acid, alkylnaphthalenesulfonic acid, alkyl diphenyl ether disulfonic acid, and a salt thereof.

Specific examples of the cationic surfactant include an alkyltrimethylammonium salt, an alkyldimethylammonium salt, an alkylbenzyldimethylammonium salt, and an alkyl amine salt.

Specific examples of the amphoteric surfactant include alkylbetaine, and alkylamine oxide.

Specific examples of the nonionic surfactant include polyoxyethylene alkyl ether, polyoxyalkylene alkyl ether, sorbitan fatty acid ester, glycerin fatty acid ester, polyoxyethylene fatty acid ester, polyoxyethylene alkylamine, and alkyl alkanolamide.

These surfactants may be used singly or in combination of two or more types of them.

Since the more surfactant is included in the polishing composition as a whole, the more improved washing efficiency of the polishing object after the polishing is achieved, the content of the surfactant in the polishing composition as a whole is 0.0001 g/L or more preferably, and more preferably 0.001 g/L or more.

Since the less surfactant is included in the polishing composition as a whole, the less surfactant remains on the polished face of the polishing object after the polishing, i.e., the more improved washing efficiency is achieved, the content of the surfactant in the polishing composition as a whole is 10 g/L or less preferably, and more preferably 1 g/L or less.

### 5-5 Water-Soluble Polymer

Water-soluble polymer may be added to the polishing composition. Such water-soluble polymer added to the polishing composition can reduce the surface roughness of the polishing object after the polishing (can be smooth).

Specific examples of the water-soluble polymer include polystyrene sulfonate, polyisoprene sulfonate, polyacrylate, polymaleic acid, polyitaconic acid, polyvinyl acetate, polyvinyl alcohol, polyglycerol, polyvinylpyrrolidone, an isoprenesulfonic acid-acrylic acid copolymer, a polyvinyl pyrrolidone polyacrylic acid copolymer, a polyvinyl pyrrolidone vinyl acetate copolymer, a salt of naphthalenesulfonate formalin condensate, diallylamine hydrochloride sulfur dioxide copolymer, carboxymethylcellulose, a salt of carboxymethylcellulose, hydroxyethylcellulose, hydroxypropylcellulose, pullulan, chitosan, and chitosan salts. These water-soluble polymers may be used singly or in combination of two or more types of them.

Since the more water-soluble polymer is included in the polishing composition as a whole, the less surface roughness at the polished face of the polishing object is obtained, the content of the water-soluble polymer in the polishing composition as a whole is 0.0001 g/L or more preferably, and more preferably 0.001 g/L or more.

Since the less water-soluble polymer is included in the polishing composition as a whole, the less water-soluble polymer remains on the polished face of the polishing object, the content of the water-soluble polymer in the polishing composition as a whole is 10 g/L or less preferably, and more preferably 5 g/L or less.

### 5-6 Preservatives and Fungicides

Preservatives and fungicides may be added to the polishing composition. Specific examples of preservatives and fungicides include isothiazoline preservatives, such as 2-methyl-4-isothiazoline-3-one and 5-chloro-2-methyl-4-isothiazoline-3-one, para-hydroxybenzonate esters, and phenoxyethanol. These preservatives and fungicides may be used singly or in combination of two or more types of them.

### 6. Method for Manufacturing Polishing Composition

A method for manufacturing a polishing composition of the present embodiment is not limited especially, and the polishing composition can be manufactured by stirring and mixing of colloidal silica with organic acid immobilized to the surface, hydrogen peroxide, salt that is at least one of ammonium nitrate and ammonium sulfate, and various types of additives as desired in fluid medium such as water.

The temperature during mixing is not particularly limited, and 10 to 40° C. is preferable. The temperature may be raised by heating to increase the rate of dissolution. The mixing duration also is not particularly limited.

### 7. Polishing Object

Although the types of the polishing object are not limited particularly, they include elemental silicon, a silicon compound and metals. Elemental silicon and a silicon compound are polishing objects having a layer including a silicon-containing material.

Examples of metals include tungsten, copper, aluminum, hafnium, cobalt, nickel, titanium, tantalum, gold, silver, platinum, palladium, rhodium, ruthenium, iridium and osmium. These metals may be included in the form of alloy or a metal compound. Of these metals, tungsten is preferable.

Examples of elemental silicon include single crystalline silicon, polycrystalline silicon (polysilicon) and amorphous silicon. Examples of a silicon compound include silicon nitride, silicon dioxide and silicon carbide. A silicon compound film includes a low-permittivity coat having specific permittivity of 3 or less. Of these silicon compounds, silicon nitride and silicon dioxide are preferable.

### 8. Polishing Method

The configuration of a polishing device is not limited particularly, and a typical polishing device can be used, which includes a holder for holding a substrate having the polishing object and a motor having changeable rotation speed and the like, and includes a polishing surface plate to which a polishing pad (polishing cloth) is attachable.

As the polishing pad, typical nonwoven fabric, polyurethane, a porous fluorine resin can be used, for example, without any particular limitation. The polishing pad used may have grooves so as to store a polishing liquid therein.

Polishing conditions are not particularly limited. For example, the rotating speed of the polishing surface plate may be 10 min⁻¹ or more and 500 min⁻¹ or less. The pressure applied to the substrate having a polishing object (polishing pressure) may be 0.7 kPa or more and 69 kPa or less.

A method for supplying the polishing composition to the polishing pad also is not particularly limited. For example, a method for supplying the composition continuously with a pump and the like may be used. The supplying amount of the composition is not limited, and preferably the surface of the polishing pad is always covered with the polishing composition. A polishing object may be polished using undiluted liquid of the polishing composition of the present embodiment, or may be polished using dilution of the polishing composition prepared by diluting the undiluted liquid ten times or more, for example, with diluting fluid such as water.

After the completion of polishing, the substrate is washed in running water, for example, and water droplets adhered to the substrate are shaken off with a spin dryer and the like for drying. Thereby, a substrate having a layer including tungsten can be obtained.

In this way, the polishing composition of the present embodiment can be used for polishing of a substrate. That is, the surface of a substrate is polished at a high polishing rate by a method of polishing the surface using the polishing composition of the present embodiment, whereby the substrate can be manufactured. Examples of the substrate include a silicon wafer having a layer including elemental silicon, silicon compounds or metals, for example.

### EXAMPLES

The following describes the present invention in more details by way of Examples and Comparative Examples.

The polishing compositions of Example 1 and Comparative Examples 1, 2 were manufactured by mixing colloidal silica with sulfonic acid immobilized to the surface, hydrogen peroxide, ammonium nitrate or ammonium acetate as salt, nitric acid as a pH adjusting agent, and water as fluid medium.

At this time, as illustrated in Table 1, Example 1 included ammonium nitrate as salt, Comparative Example 1 included ammonium acetate as salt, and Comparative Example 2 did not include salt.

As illustrated in Table 1, the content of the colloidal silica with sulfonic acid immobilized to the surface in the polishing composition as a whole was 4% by mass in Example 1 and Comparative Example 1, and 6% by mass in Comparative Example 2.

The average primary particle diameter of the colloidal silica with sulfonic acid immobilized to the surface was 32 nm in all of Example 1 and Comparative Examples 1 and 2, and the average secondary particle diameter was 70 nm in all of them.

The value of pH of the polishing compositions adjusted by the pH adjusting agent was 2.1 in all of Example 1 and Comparative Examples 1 and 2. The content of hydrogen peroxide in the polishing composition as a whole was 4.65 g/kg (0.465% by mass) in all of Example 1 and Comparative Examples 1 and 2.

Using any one of the polishing compositions in Example 1 and Comparative Examples 1, 2, a wafer of 200 mm in diameter was polished under the following polishing condition 1 or polishing condition 2 (see polishing test examples 1 to 6 in Table 1). The polished wafers were a silicon wafer with a tungsten film and a silicon wafer with a silicon dioxide film (tetraethoxysilane film). In the following Table 1, “W” indicates the silicon wafer with a tungsten film and “TEOS” indicates the silicon wafer with a silicon dioxide film (tetraethoxysilane film).

### Polishing Condition 1

Polishing device: CMP one-side polishing device for 200 mm wafer

Polishing pad: Polishing pad made of polyurethane

Polishing pressure: 12.4 kPa

Rotating speed of polishing surface plate: 97 min⁻¹

Rotating speed of carrier: 100 min⁻¹

Supplying amount of polishing composition: 200 mL/min

Polishing duration: 60 seconds

### Polishing Condition 2

Polishing device: CMP one-side polishing device for 200 mm wafer

Polishing pad: Polishing pad made of polyurethane

Polishing pressure: 20.7 kPa

Rotating speed of polishing surface plate: 97 min⁻¹

Rotating speed of carrier: 100 min⁻¹

Supplying amount of polishing composition: 200 mL/min

Polishing duration: 60 seconds

For the silicon wafer with a tungsten film, the thickness of the tungsten film before polishing and after polishing was measured using a sheet resistance measuring instrument based on a DC 4-probe method as a principle. Then, the polishing rate of tungsten was calculated from the difference in thickness and polishing duration. For the silicon wafer with a silicon dioxide film (tetraethoxysilane film), the thickness of the silicon dioxide film before polishing and after polishing was measured using an optical interference type film-thickness measuring instrument. Then, the polishing rate of silicon dioxide was calculated from the difference in thickness and polishing duration. Table 1 illustrates the result.

TABLE 1

| | | | | | | | | Polishing | |
|---|---|---|---|---|---|---|---|---|---|
| | | Concentration of | Salt | | | | | rate | |
| | Polishing | colloidal silica | | Concentration | pH adjusting agent | | Polishing | [nm/min] | |
| | composition | [% by mass] | Types | [% by mass] | [% by mass] | pH | condition | W | TEOS |
| Polishing | Ex. 1 | 4 | Ammonium nitrate | 2 | 0.1 | 2.1 | 1 | 25.6 | 56.2 |
| test ex. 1 | | | | | | | | | |
| Polishing | Ex. 1 | 4 | Ammonium nitrate | 2 | 0.1 | 2.1 | 2 | 48.2 | 112.2 |
| test ex. 2 | | | | | | | | | |
| Polishing | Comp. Ex. 1 | 4 | Ammonium acetate | 2 | 1.6 | 2.1 | 1 | 19.0 | 56.7 |
| test ex. 3 | | | | | | | | | |
| Polishing | Comp. Ex. 1 | 4 | Ammonium acetate | 2 | 1.6 | 2.1 | 2 | 42.3 | 105.0 |
| test ex. 4 | | | | | | | | | |
| Polishing | Comp. Ex. 2 | 6 | Not included | — | 0.1 | 2.1 | 1 | 24.3 | 39.7 |
| test ex. 5 | | | | | | | | | |
| Polishing | Comp. Ex. 2 | 6 | Not included | — | 0.1 | 2.1 | 2 | 44.4 | 72.6 |
| test ex. 6 | | | | | | | | | |

The result of the polishing test examples 1 to 6 in Table 1 illustrates that polishing using the polishing composition of Example 1 enabled polishing of all of the wafers at a higher polishing rate than that using the polishing compositions of Comparative Examples 1, 2. It is also illustrated that the polishing composition of Example 1 had a larger polishing rate of tungsten than that of Comparative Examples 1 and 2.

Next, another polishing composition was manufactured. That is, the polishing compositions of Examples 11 to 14 and Comparative Examples 11, 12 were manufactured by mixing colloidal silica with sulfonic acid immobilized to the surface, hydrogen peroxide, salt that was ammonium nitrate, maleic acid as a pH adjusting agent, and water as fluid medium.

At this time, as illustrated in Table 2, Examples 11 to 13 included ammonium nitrate as salt, Example 14 included ammonium sulfate as salt, and Comparative Examples 11, 12 did not include salt.

As illustrated in Table 2, the content of the colloidal silica with sulfonic acid immobilized to the surface in the polishing composition as a whole was 6% by mass in all of Examples 11 to 14 and Comparative Examples 11, 12.

The average primary particle diameter of the colloidal silica with sulfonic acid immobilized to the surface was 32 nm in all of Examples 11 to 14 and Comparative Examples 11 and 12, and the average secondary particle diameter was 70 nm in all of them.

The value of pH of the polishing compositions adjusted by the pH adjusting agent was as illustrated in Table 2. The content of hydrogen peroxide in the polishing composition as a whole was 2.17 g/L (0.213% by mass) in all of Examples 11 to 14 and Comparative Examples 11 and 12.

Using the polishing compositions in Examples 11 to 14 and Comparative Examples 11, 12, a wafer of 300 mm in diameter was polished under the following polishing condition 3 (see polishing test examples 11 to 16 in Table 2). The polished wafers were a silicon wafer with a tungsten film, a silicon wafer with a silicon dioxide film (tetraethoxysilane film), and a silicon wafer with a silicon nitride film. In the following Table 2, “W” indicates the silicon wafer with a tungsten film, “TEOS” indicates the silicon wafer with a silicon dioxide film (tetraethoxysilane film), and “SiN” indicates the silicon wafer with a silicon nitride film.

### Polishing Condition 3

Polishing device: CMP one-side polishing device for 300 mm wafer

Polishing pad: Polishing pad made of polyurethane

Polishing pressure: 10.3 kPa

Rotating speed of polishing surface plate: 93 min⁻¹

Rotating speed of carrier: 87 min⁻¹

Supplying amount of polishing composition: 200 mL/min

Polishing duration: 60 seconds

For the silicon wafer with a tungsten film, the thickness of the tungsten film before polishing and after polishing was measured using a sheet resistance measuring instrument based on a DC 4-probe method as a principle. Then, the polishing rate of tungsten was calculated from the difference in thickness and polishing duration. For the silicon wafer with a silicon dioxide film (tetraethoxysilane film) and the silicon wafer with a silicon nitride film, the thickness of these films before polishing and after polishing was measured using an optical interference type film-thickness measuring instrument. Then, the polishing rate of silicon dioxide and silicon nitride was calculated from the difference in thickness and polishing duration. Table 2 illustrates the result.

TABLE 2

| | | Concentration of | Salt | | | | Polishing | | |
|---|---|---|---|---|---|---|---|---|---|
| | Polishing | colloidal silica | | Concentration | | Polishing | rate [nm/min] | | |
| | composition | [% by mass] | Types | [% by mass] | pH | condition | W | TEOS | SiN |
| Polishing | Ex. 11 | 6 | Ammonium nitrate | 0.5 | 4.3 | 3 | 18.3 | 32.5 | 23.4 |
| test ex. 11 | | | | | | | | | |
| Polishing | Ex. 12 | 6 | Ammonium nitrate | 0.5 | 3.1 | 3 | 20.1 | 39.5 | 31.0 |
| test ex. 12 | | | | | | | | | |
| Polishing | Ex. 13 | 6 | Ammonium nitrate | 1 | 4.3 | 3 | 21.6 | 39.7 | 23.7 |
| test ex. 13 | | | | | | | | | |
| Polishing | Ex. 14 | 6 | Ammonium sulfate | 1 | 5.0 | 3 | 15.4 | 35.6 | 27.1 |
| test ex. 14 | | | | | | | | | |
| Polishing | Comp. Ex. 11 | 6 | Not included | — | 4.3 | 3 | 3.1 | 6.3 | 19.7 |
| test ex. 15 | | | | | | | | | |
| Polishing | Comp. Ex. 12 | 6 | Not included | — | 5.0 | 3 | 2.0 | 4.2 | 2.5 |
| test ex. 16 | | | | | | | | | |

The result of the polishing test examples 11 to 16 in Table 2 illustrates that polishing using the polishing compositions of Examples 11 to 14 enabled polishing of all of the silicon wafers at a higher polishing rate than that using the polishing compositions of Comparative Examples 11, 12. It is also illustrated that the polishing compositions of Example 11 to 14 had a larger polishing rate of tungsten than that of Comparative Examples 11 and 12.

1.-11. (canceled)

12. A polishing composition, comprising: colloidal silica with organic acid immobilized to a surface of the colloidal silica; hydrogen peroxide; and salt, the salt being at least one of ammonium nitrate and ammonium sulfate.

13. The polishing composition according to claim 12, wherein the organic acid is sulfonic acid.

14. The polishing composition according to claim 12, wherein the polishing composition has pH of 5 or less.

15. The polishing composition according to claim 12, wherein content of the salt is 0.01% by mass or more and 5.0% by mass or less.

16. The polishing composition according to claim 12, wherein content of the hydrogen peroxide is 0.01% by mass or more and 10% by mass or less.

17. The polishing composition according to claim 12, wherein the polishing composition is for polishing tungsten.

18. A method for polishing, comprising polishing a polishing object using the polishing composition according to claim 12.

19. The method for polishing, according to claim 18, wherein the polishing object comprises tungsten.

20. A method for manufacturing the polishing composition according to claim 12, comprising mixing the colloidal silica, the hydrogen peroxide, the salt and fluid medium.

21. A substrate having a surface that is polished using the polishing composition according to claim 12.

22. A method for manufacturing a substrate, comprising polishing a surface of the substrate using the polishing composition according to claim 12.

23. The polishing composition according to claim 13, wherein the polishing composition has pH of 5 or less.

24. The polishing composition according to claim 13, wherein content of the salt is 0.01% by mass or more and 5.0% by mass or less.

25. The polishing composition according to claim 14, wherein content of the salt is 0.01% by mass or more and 5.0% by mass or less.

26. The polishing composition according to claim 13, wherein content of the hydrogen peroxide is 0.01% by mass or more and 10% by mass or less.

27. The polishing composition according to claim 14, wherein content of the hydrogen peroxide is 0.01% by mass or more and 10% by mass or less.

28. The polishing composition according to claim 15, wherein content of the hydrogen peroxide is 0.01% by mass or more and 10% by mass or less.

29. The polishing composition according to claim 13, wherein the polishing composition is for polishing tungsten.

30. The polishing composition according to claim 14, wherein the polishing composition is for polishing tungsten.

31. The polishing composition according to claim 15, wherein the polishing composition is for polishing tungsten.
